(19) United States
(12) Patent Application Publication
(10) Pub. No.: US 2002/0130050 A1
(43) Pub. Date: Sep. 19, 2002

(54) Apparatus and method for enhanced biomass production with electrical waveform shaping

(75) Inventor: David B. Goodson, Snohomish, WA (US)

Correspondence Address: SEED INTELLECTUAL PROPERTY LAW GROUP PLLC, 701 FIFTH AVE, SUITE 6300, SEATTLE, WA, 98104-7092, US

(73) Assignee: MycoFerm Technologies, Inc, Bellevu, WA

(21) Appl. No.: 10/121,571

(22) Filed: Apr. 12, 2002

Related U.S. Application Data
(63) Continuation of application No. 09/760,214, filed on Jan. 12, 2001.
(60) Provisional application No. 60/176,717, filed on Jan. 14, 2000.

(51) Int. Cl. C30B 7/12; C30B 9/14

(52) U.S. Cl. 205/687

(57) ABSTRACT

Apparatus and method for enhanced biomass production by electrical waveform shaping are disclosed. The invention relates to cultivating a biological source cell in a liquid-medium bioreactor and applying a waveform regulated electric field potential to the source cell, wherein the liquid medium comprises one or more ionizable components. The waveform that regulates the applied field potential comprises a plurality of modes such that at least one mode orders an applied field potential capable of generating an ion from the ionizable component and at least one mode orders an applied field potential capable of inducing migration of the generated ion within the liquid medium. Related apparatus and methods are also disclosed.

### CROSS-REFERENCES TO RELATED APPLICATIONS

This application claims the benefit of U.S. Provisional Patent Application No. 60/176,717 filed Jan. 14, 2000, which is incorporated herein by reference in its entirety.

### TECHNICAL FIELD

The present invention relates generally to production of biomass, and in particular to a process for generating biomass in a bioreactor by applying a waveform regulated electric field potential.

### BACKGROUND OF THE INVENTION

Cell growth in bioreactors provides a tool for research and production in a wide variety of commercial and industrial contexts, including pharmaceutical, nutritional, chemical, environmental and other applications. Depending on the specific biological organism being cultured, various configurations of bioreactor hardware and software have been devised in efforts to optimize biomass production, for example, to increase yields of fermentation products or to maximize cell growth by maximizing volumetric productivity (g l⁻¹ h⁻¹) by high cell-density cultivation (HCDC). Bioreactors often may comprise containers of various shapes, dimensions and materials, such as tanks, chambers, tubes, kettles, flasks or the like fabricated from glass, metal, plastic, polymer, ceramic, membranes including ceramic and/or dialysis membranes or other suitable materials selected according to the particular organism and process to be used. For a review of HCDC, see, e.g., Riesenberg et al., 1999 Appl. Microbiol. Biotechnol. 51:422-430.

For a variety of reasons, undesirable settling of cultured cells or organisms, or accumulation of noxious, toxic or inhibitory products or by-products in the bioreactor, may impair the efficiency of biomass production. For example, settling, aggregation or clumping of growing cell cultures into a slurry or sludge can retard cell growth rates by preventing access of the cells to microenvironments having an optimal nutrient, gas and/or pH balance. Attempts to mitigate these and related problems among the many bioreactor configurations known to the art include redistribution of the bioreactor contents by subjecting the bioreactor to regular, physical movement or by introducing a pump, circulator, agitator, stirrer, mixer, impeller, lift, airlift or other device into the bioreactor for this purpose; introduction of microcarrier particles to provide suspension substrates for cell growth; or sparging the bioreactor by bubbling a suitable gas through the liquid medium slurry. These and other bioreactor designs known to the art, however, suffer from one or more shortcomings, such as mechanical damage to the cultured cells in the bioreactor, suitability of some but not other specific cells or organisms for propagation in a particular bioreactor configuration, persistent difficulty in maintaining optimal growth conditions for a maximum number of cells and other problems. For example, limited solubility of nutrients and other solid and gaseous substrates in the medium, product instability, degradation or volatility, increased medium viscosity, inability to maintain optimal mixing in a pseudoplastic fluid such as a liquid medium containing a high biomass concentration, high evolution of carbon dioxide and/or heat, and high oxygen demand may all impair volumetric productivity (Riesenberg et al., 1999).

Clearly there is a need for an improved process and a suitable bioreactor for producing biomass from a wide range of organisms and cell types under a wide range of conditions. The present invention provides improved apparatus and methods for generating biomass, including accelerated rates of cell growth and proliferation, and enhanced yields of biological materials, and offers other related advantages.

### SUMMARY OF THE INVENTION

The present invention provides an apparatus and method for enhanced biomass production through the use of electrical waveform shaping. Accordingly, it is an aspect of the invention to provide a method for enhancing biomass production in a bioreactor, comprising providing a liquid-medium bioreactor that comprises (a) a liquid-medium containment vessel having an axis and comprising a wall and a floor and containing a liquid medium, and (b) a first and a second electrode mounted on said wall and mutually opposed along said axis of the liquid-medium containment vessel and immersed in the liquid medium, wherein (i) the first electrode comprises a first electrode surface and the second electrode comprises a second electrode surface, and said first and second electrode surfaces are substantially parallel to one another, and (ii) the first and second electrodes are insulated from said wall and said floor of the containment vessel, wherein said liquid medium comprises at least one ionizable component; and applying a waveform-regulated electric field potential to at least one biological source cell within the liquid medium in the liquid-medium bioreactor, wherein said waveform regulated electric field potential comprises a first waveform mode field potential capable of generating at least one ion from the ionizable component when applied to the liquid medium, and a second waveform mode field potential capable of inducing migration of said ion within the liquid medium when said second waveform mode field potential is applied to the liquid medium, and thereby enhancing biomass production in the bioreactor.

In certain embodiments, the liquid-medium containment vessel further comprises at least one liquid-medium circulation chamber immersed in the liquid medium, said circulation chamber being in fluid communication with a separate liquid-medium reservoir; (b) at least one electrode of the liquid-medium containment vessel is positioned within the liquid-medium circulation chamber, said liquid-medium circulation chamber comprising (i) a continuous permeable membrane wall situated between the electrode and the biological source cell, and (ii) a conduit to said separate liquid-medium reservoir; and (c) said separate liquid-medium reservoir comprises (i) a closed tank having liquid medium therein, (ii) a circulating means for circulating liquid medium between the liquid-medium circulation chamber and the separate liquid-medium reservoir, and (iii) an ion trap in fluid communication with the interior of the tank; whereby circulation of liquid medium between the liquid-medium circulation chamber and the separate liquid-medium reservoir permits trapping of at least one ion from the liquid medium in the ion trap. According to certain further embodiments (a) the first electrode is positioned within a first liquid-medium circulation chamber that is in fluid communication with a first separate liquid-medium reservoir comprising a first ion trap, and (b) the second electrode is positioned within a second liquid-medium circulation chamber that is in fluid communication with a second separate liquid-medium reservoir comprising a second ion trap, whereby circulation of liquid medium between the first liquid-medium circulation chamber and the first separate liquid-medium reservoir permits trapping of at least one first species of ion from the liquid medium in the first ion trap and circulation of liquid medium between the second liquid-medium circulation chamber and the second separate liquid-medium reservoir permits trapping of at least one second species of ion from the liquid medium in the second ion trap.

In another embodiment the waveform regulated electric field potential is bimodal, and in another embodiment the waveform regulated electric field potential comprises at least three modes. In certain embodiments, the biological source is a prokaryote, an archaebacterium or a eukaryote. In certain further embodiments, the prokaryote is Escherica coli, Staphylococcus aureus, Pseudomonas aeruginosa or Bacillus thuringiensis. In other embodiments the eukaryote is a yeast, a fungus, a plant, an invertebrate animal or a vertebrate animal. In certain further embodiments the yeast is Phaffia rhodozyma, Saccharomyces cerevisiae, Schizosaccharomyces pombe, Pichia pastoris, Pichia stipitis, Candida utilis, Candida albicans, Candida guilliermondii or Cryptococcus albidus. In certain other embodiments, the fungus is Metarhizium flavivoride, Beauvueria bassiana, Paecilomyces fumosoreus or Gladiocladium fimbriatum. In certain other embodiments the plant is Taxus brevifolia. In other embodiments the invertebrate animal is a nematode (e.g., C. elegans) or an insect (e.g., Trichoplusia ni). . In other embodiments the vertebrate animal is a reptile, an amphibian, a bird, a fish or a mammal. In certain further embodiments the mammal is a human, a non-human primate, a rodent, a bovine, an equine, an ovine and a porcine. In another embodiment, the archaebacterium is Marinococcus or Sulfolobus shibatae.

In certain other embodiments the liquid medium is an aqueous medium. In certain embodiments the liquid medium comprises 1% yeast extract, 2% tryptone peptone and 2% dextrose. In certain embodiments the ionizable component is water, and in certain other embodiments the ionizable component is an organic molecule having a hydroxyl group. In certain embodiments the ion is singlet oxygen, Cl⁻, Na⁺, K⁺ or ammonium.

According to certain embodiments of the present invention, the first waveform mode field potential is at least 12.3 volts. According to certain other embodiments, the second mode field potential is not greater than one volt.

These and other aspects of the present invention will become apparent upon reference to the following detailed description and attached drawings. All references disclosed herein are hereby incorporated by reference in their entirety as if each was incorporated individually.

### BRIEF DESCRIPTION OF THE DRAWINGS

FIG. 1 shows an example of a liquid-medium bioreactor.

FIG. 2 shows an example of an electrode for use in a liquid-medium bioreactor.

FIG. 3 shows a growth profile of S. cerevisiae cultivated in a liquid-medium bioreactor.

FIG. 3 depicts enhanced biomass production by applying a waveform-regulated electric field potential to a biological source cell in a liquid medium bioreactor.

FIG. 4 depicts a waveform for regulating an applied electric field potential.

### DETAILED DESCRIPTION OF THE INVENTION

The present invention pertains in part to the unexpected discovery that remarkable enhancements of biomass production can be achieved in a bioreactor by applying a waveform regulated electric field potential to a liquid medium containing a cell derived from a biological source. The invention therefore provides an improved apparatus and method for generating biomass, including accelerated rates of cell growth and proliferation, and enhanced yields of biological materials. In particular, the invention relates in part to the surprising observation that desirable bioreactor conditions that are favorable for maintenance of a wide variety of biological source cells, and concomitant augmentation of biomass production, can be effected through waveform regulated electric potentials that initiate generation of specific gas ions from liquid medium components. The invention thus also provides electrohydrodynamic mixing within a liquid-medium bioreactor in a manner that does not require bubbling gas sparging, airlift devices, agitators or other mechanical mixing strategies.

### LIQUID MEDIUM

A liquid medium for use in a bioreactor according to the present invention includes any suitable liquid solution, suspension, formulation, mixture or the like for biological source cell growth that is in liquid form under the conditions used for enhancing biomass production and that comprises at least one ionizable component. A suitable liquid medium may be selected by a person having ordinary skill in the art based on the particular biological source cell to be cultivated, as known in the art and provided herein. Typically, a useful liquid medium that comprises at least one ionizable component will further comprise appropriate solutes, for example, suitable salts and/or sugars to maintain isotonicity with the biological source cell; nutrients as may be required for a particular biological source cell, such as an energy source, a carbon source, a nitrogen source, essential amino acids, vitamins, cofactors and the like; pH buffering agents; and optionally additional stabilizers, growth factors, proteins, metabolites, serum or other biological source cell liquid medium additives. In particularly preferred embodiments the liquid medium is an aqueous medium, wherein water and/or another medium component may be the ionizable component as provided herein. Chemically defined media represent preferred liquid media and have been extensively characterized for use with a variety of cell types, including use in bioreactors (for review, see, e.g., Zhang et al., 1999 Appl. Microbiol. Biotechnol. 51:407; see also, e.g., Reddy et al., 1999 Appl. Microbiol. Biotechnol. 51:614; Zhang et al. 1996 Appl. Microbiol. Biotechnol. 44:568). Numerous other liquid media that support biological source cell growth (e.g., cell division) and/or product formation (e.g., cellular gene expression, production or elaboration of desired products, including proteins, enzymes, nucleic acids, lipids, carbohydrates or other biochemical intermediates, metabolites, catabolites, substrates, precursors, cofactors or the like) are known for many particular biological source cells as provided herein, or can be readily determined by routine screening and without undue experimentation by a person familiar with the art, based on the present disclosure.

As noted above, a liquid medium according to the present invention comprises at least one ionizable component. In preferred embodiments the liquid medium is an aqueous medium and at least one ionizable component therein is water which, when a waveform regulated electric field potential is applied to the liquid medium, may be electrolytically dissociated to produce monatomic oxygen (O⁻) anion. Without wishing to be bound by theory, according to the present invention the first waveform mode (of a waveform having a plurality of modes) regulates a first waveform mode field potential (i.e., an initial pulse voltage) that induces ionization of an ionizable component of the liquid medium to generate a desired ion by a process that, by virtue of the transient nature of the first waveform mode and as a function of the full waveform, which may further be a function of the bioreactor containment vessel dimensions and/or geometry, is not deleterious to biological source cells.

Accordingly, in the embodiment just described, the first waveform mode field potential induces the generation of oxygen anion from the ionizable medium component water, but the invention need not be so limited. Depending upon, inter alia, the composition of the liquid medium, the waveform selected to regulate the application of electric field potentials to the medium and the particular response properties of a selected biological source cell to the field potentials ordered by the waveform under the conditions employed, a wide variety of desired ionic species may be generated from an appropriately formulated liquid medium.

Thus, a liquid medium for use according to the invention may contain any of a wide variety of ionizable components, the ionization of which may be induced by a waveform regulated electric field potential applied to the biological source cell in the liquid medium in a bioreactor. Examples of ions so generated that may be useful for enhancing biomass production include monatomic oxygen (O⁻) anion, carbonium (C⁺) ion, ammonium (NH₄⁺) ion and other ionic species that will depend upon various factors, including the composition of the liquid medium, the bioreactor and electrode configurations and the waveform employed (all of which may be selected and regulated to produce a desired conductivity), as well as other factors. Ionizable components may also include organic molecules, many of which comprise structures that are readily amenable to electron gain or loss, to generate ionic species. For example, ionizable components that are organic molecules having hydroxyl groups may be present in liquid media according to certain preferred embodiments of the invention. According to nonlimiting theory, ionizable components including organic molecules may but need not provide a source of nutritional or respiratory metabolites to a growing biomass. For instance, certain ionic species that may be derived from liquid medium ionizable components as provided herein may not enhance food properties of the liquid medium per se, but may serve an adjunctive mixing role that enhances biomass production.

### LIQUID-MEDIUM BIOREACTOR

A suitable bioreactor for use according to the present invention may be virtually any bioreactor that can contain liquid medium as provided herein, and that has or can be equipped with first and second electrodes, as also described herein. Thus, a liquid medium bioreactor comprises a liquid-medium containment vessel comprising a wall and a floor and containing a liquid medium, which refers to a container having any of various shapes, dimensions and materials, such as a tank, chamber, tube, kettle, flask or the like fabricated from glass, metal, plastic, polymer, ceramic, membranes including ceramic and/or dialysis membranes or other suitable materials or combinations of materials selected according to the particular organism, liquid medium and process to be used.

For purposes of determining electrode mounting positions, the liquid-medium containment vessel has an axis that may in certain preferred embodiments be a longitudinal axis, but the invention need not be so limited, such that symmetrical (e.g., radially symmetrical) or asymmetrical (e.g., irregularly shaped) liquid-medium containment vessels may also be selected. A first and a second electrode are mounted on the wall of the liquid-medium containment vessel at opposite ends along the axis, each electrode comprising an electrode surface such that the mounted electrode surfaces are immersed in the liquid medium and substantially parallel to one another, i.e., a plane defined by the first electrode surface is parallel or very nearly parallel to a plane defined by the second electrode surface. For instance, in certain embodiments wherein the liquid medium containment vessel has a longitudinal axis, positioning of the electrodes may be performed in a manner such that waveform-regulated, applied electric field lines may be focused within a semiconductive liquid medium to create a region of electromagnetic field focus, such that one or more particular species within the liquid medium accumulate preferentially in that region. According to certain further embodiments, circulation of the liquid medium in the vicinity of the vessel wall, as described in greater detail below, may further promote such preferential accumulation.

The electrodes are mounted in a manner that insulates them from (i.e,. impairs conductance of any electric current applied through the electrodes to) the wall and floor of the liquid-medium containment vessel and provides delivery of electric field potential substantially to the liquid medium, where such insulation may be accomplished by any of a number of designs with which those having skill in the art will be familiar, including selection of non-conducting materials for the construction of the containment vessel wall and floor. Electrodes may be constructed from a variety of conductive materials that are known in the art and that may be designed to have the desired size, shape and chemical compatibility with the liquid medium. Examples of electrode materials include stainless steel, copper, graphite, silver, aluminum and platinum that may, depending on the size and shape of the liquid-containment vessel, be provided as wires, sheets, plates, coils, arrays or other configurations.

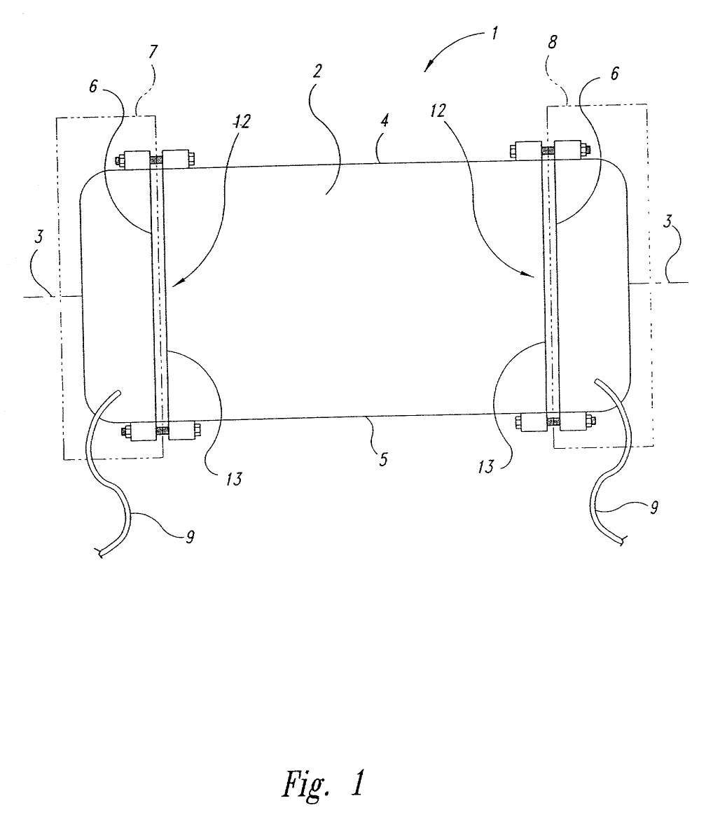

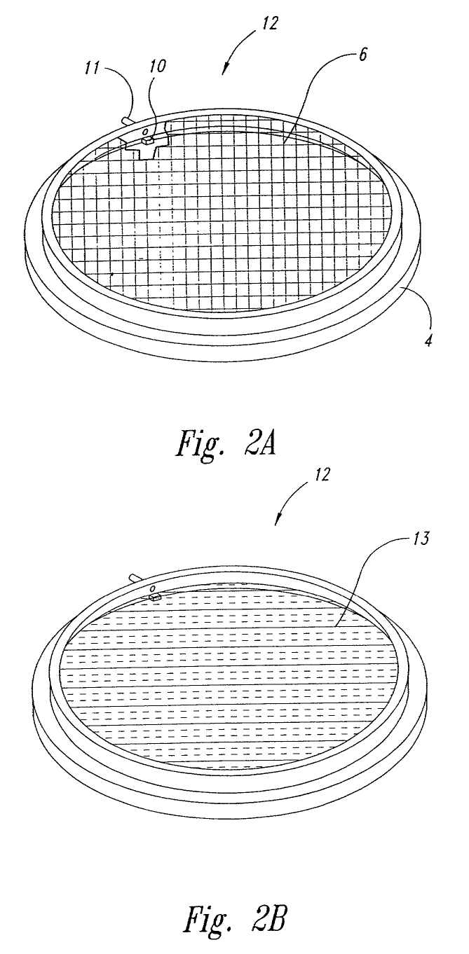

Turning to FIG. 1 there is provided an exemplary pictorial illustration of a liquid-medium bioreactor 1 for use according to the present invention. The bioreactor comprises a liquid-medium containment vessel 2 having an axis 3 and comprising a wall 4 and a floor 5 for containing liquid medium. A first electrode 6 in a first liquid-medium circulation chamber 7 and a second electrode 6 in a second liquid-medium circulation chamber 8 are mounted on the wall and mutually opposed along the axis 3. A conduit 9 provides fluid communication to a separate liquid-medium reservoir. FIG. 2A provides an exemplary front perspective pictorial illustration of an electrode housing 12 mounted in a section of liquid-medium containment vessel wall 4 and comprising a perforated stainless steel electrode surface 6 in electrode communication with a stainless steel contact 10 that is in communication to the exterior of the bioreactor through an insulated port 11. A reverse perspective pictorial illustration of the electrode housing 12 is provided in FIG. 2B, which shows a permeable membrane 13 that is positioned between the electrode surface and the biological source cell, thereby forming a liquid-medium circulation chamber 7 that contains the electrode surface.

In a certain embodiment of the invention, the liquid-medium containment vessel further comprises at least one liquid-medium circulation chamber that is immersed in the liquid medium and in fluid communication with a separate liquid-medium reservoir. In this embodiment, at least one electrode is positioned within the liquid-medium circulation chamber, which comprises a continuous permeable membrane wall situated between the electrode and the biological source cell and a conduit for the passage of fluid to and from the separate liquid-medium reservoir. A variety of suitable materials may be employed for the permeable membrane wall, depending on the desired physicochemical properties, which will derive in part from the bioreactor conditions to be used (e.g., temperature, pH, applied field, etc.) and will in any event be sufficient to exclude the biological source cell from the circulation chamber. For instance, suitable permeable membranes may include dialysis membranes (e.g., Portner et al., 1998 Appl. Microbiol. Biotechnol. 50:403); gas permeable membranes (e.g., U.S. Pat. No. 6,001,642, U.S. Pat. No. 5,763,279 and references cited therein); ceramic, metallic, nylon, polymer or fiber membranes, or a membrane made from any other suitable material.

Accordingly and in certain particularly preferred embodiments, at least one and preferably two electrodes are separated from the biological source cell by a continuous permeable membrane wall having desired physicochemical properties. For instance, in certain embodiments a membrane material may be employed that exhibits selective properties with regard to the molecular weight and/or charge (or other properties including those noted below) of solutes (including ionic species) capable of passing through such a membrane. The membrane material selected to surround the anode may, but need not, be the same as the membrane material selected to surround the cathode. In these and related embodiments, the membranes may specifically allow an ion generated from an ionizable medium component as provided herein to pass from the vicinity of a first electrode through the membranes to the vicinity of a second electrode. Without wishing to be bound by theory, according to such embodiments an ionizable component may, as its ionic state is altered, pass to and from distinct liquid-medium circulation chambers containing electrodes of opposite polarities, permitting energy transfer to the liquid medium in the form of electrical current (e.g., movement of ions). In this manner the environment of the biological source cell can be varied, for example, to maintain such cells in a desired level of one or more particular ionized components (e.g., oxygen). Similarly and in related embodiments, the invention contemplates the use of waveform regulated electric field potentials in a liquid-medium bioreactor to effect movement of a medium component, of a product of a chemical modification of a medium component, or of biomass, including preferential migration of a selected portion of biomass (e.g., cells, one or more protein species, other biomass products, etc.), to a desired position in the bioreactor.

As further examples, according to such embodiments a membrane, such as a permeable or semipermeable membrane, may be used that permits desirable ionic migration for certain species (e.g., oxygen, ammonium, carbonium, etc.) while excluding from transmembrane passage certain other ionized species (e.g. peptides, proteins, sugars, carbohydrates, etc.). Membranes capable of effecting such selectivity are known to those having ordinary skill in the art, as also noted above. The use of such membranes affords certain advantages that will be readily appreciated, such as preventing the undesired depletion from the liquid medium, during biomass generation in the bioreactor, of specific liquid medium components (e.g., proteins, sugars, amino acids, carbohydrates, etc.) by limiting the access of such components to the electrodes, or limiting electrode fouling. Suitable membranes, in addition to those described elsewhere herein, may include Magna™ nylon transfer membranes (MSI, Westboro, Mass.), Celgard™ membranes (Separations Products Division, Hoechst Celanese Corp., Summit, N.J.), Sartorious membranes (#11606, Sartorious Corp., Edgewood, N.Y.), Millipore membranes (Millipore Corp., Bedford, Mass.) or other membranes having the desired permeability properties (e.g., molecular weight exclusion limits for solutes, particle size exclusion limits for suspended particles, charge properties, hydrophobicity, hydrophilicity, tensile strength, chemical resistance, thermal resistance, etc.) according to the particular conditions to be employed. Such membranes may also in certain embodiments provide an aseptic barrier between the electrodes, which may not exist in a sterile environment, and the biological source cell in liquid medium which typically may be desirably maintained as a sterile suspension.

Whereas it may be particularly preferred to employ membranes that are situated between electrode and biological source cell, as noted above, the present invention need not be so limited and contemplates certain embodiments wherein such membranes may not be present. The suitability of the bioreactor configuration (i.e., with or without a membrane protecting the electrode) may therefore depend in part on a variety of factors, including the nature of the biological source cell, the composition of the liquid medium, the composition of the bioreactor itself including the electrode composition, the waveform regulated electric field potential, the duration of the biomass production, or any number of other factors that will be appreciated by the ordinarily skilled artisan. For example, in certain such embodiments bioreactor configurations may be amenable to aquaculture and/or plant hydroponic cultures, whereby the positioning of one or more electrodes within a bioreactor may be accomplished without the use of a permeable membrane.

The separate liquid-medium reservoir comprises a closed tank having liquid medium therein, a circulating means for circulating liquid medium between the liquid-medium circulation chamber and the separate liquid-medium reservoir, and an ion trap in fluid communication with the interior of the closed tank. According to this embodiment, liquid medium is circulated between (i) the liquid-medium circulation chamber immersed in the liquid medium within the liquid-medium containment vessel of the bioreactor, and (ii) the separate liquid-medium reservoir in a manner that permits trapping of at least one ion from the liquid medium in the ion trap.

The ion trap may be any device, apparatus, column, chamber, filter, cartridge, matrix or the like with which the liquid medium may retrievably come into contact such that at least one ion, for instance, an electrolytic by-product generated by application of a waveform-regulated electric field potential, is removed from the liquid medium. Liquid medium so depleted of at least one ion is then returned to the circulation chamber by the circulating means. In a preferred embodiment, the ion trap removes ions from the liquid medium by attraction of the ions to be removed to an electrical charge that is maintained at the surface of the ion trap that contacts the liquid medium.

For example, the ion trap may comprise an electrode connected to an electrical current source and constructed of a conductive material that is compatible with the liquid medium. Preferably, such an ion trap electrode is configured to have a large surface area relative to the liquid medium volume that may contact such an electrode at any given time. For instance, a conductive metal mesh or screen or a perforated metal sheet or the like may provide a useful electrode for an electrode ion trap. Typically, part or all of the electrode contact surface provides a region for enhanced removal of ions from the liquid medium, which in certain embodiments may be undesirable by-products that may adversely affect biomass production, and in other embodiments may be usefully recovered products. In certain embodiments of the invention, the ion trap electrode is used in conjunction with a waveform-regulated electric field potential, which may be regulated by the same waveform that regulates the potential applied to the liquid-medium containment vessel electrodes or may be an independent waveform. In certain other embodiments the ion trap electrode may be connected to, or a part of, a liquid-medium containment vessel electrode.

Alternatively, the ion trap may employ chemical rather than electrical charge to remove ions from the liquid medium. Such a chemical ion trap, for example, may take the form of a solid-phase ion exchange medium and, depending upon the ion exchange medium selected, may provide the further advantage of ion selectivity. Numerous electrode materials and chemical ion exchange materials are known to those familiar with the art and can be selected in view of the teachings herein.

By way of non-limiting theory, sequestration of the electrode within the liquid-medium circulation chamber prevents direct contact of the biological source cell with the electrode, thereby reducing or eliminating electrode fouling. This configuration also permits applied field potentials to migrate through the entire liquid medium contents of the liquid-medium containment vessel by virtue of their passage through the permeable membrane wall of the circulation chamber into the region of the containment vessel occupied by the biological source cell. The circulation of liquid medium between the circulation chamber and the separate reservoir further permits removal from the containment vessel of undesirable contaminants that may otherwise accumulate in the vicinity of the electrode, for example, certain ionized species generated by the waveform regulated electric field potential that may have deleterious effects on volumetric productivity, including reactive free radicals, noxious or toxic gases or other species.

It will be appreciated that the circulation means may take various forms, depending on the configuration of the liquid-medium containment vessel, the circulation chamber, the separate liquid-medium reservoir and the ion trap, so long as medium is removed from the circulation chamber (e.g., contaminated medium is removed from the vicinity of the electrode) to the reservoir and replaced with a comparable volume of medium from the reservoir (e.g., decontaminated or fresh medium). Moreover, the circulation means may be located anywhere within the bioreactor provided it is capable of creating a suitable motive force within the liquid medium to ensure continual withdrawal of medium from the circulation chamber and replacement of such withdrawn medium with a substantially equivalent volume of medium from the liquid-medium reservoir. In certain embodiments the circulation means may be provided by the configuration of the liquid-containing components of the bioreactor alone or in concert with mixing effects produced by one or more of ion injection, ion irrigation, ion migration or other electrohydrodynamic effects provided by the apparatus and method of the present invention. In certain other embodiments, the circulation means may be provided by a pump, a turbine, a motor, a hydraulic device, a hydrostatic, gravitational or capillary-driven device, or any other suitable device for circulating liquid medium as provided herein and with which those having ordinary skill in the art will be familiar.

In certain other embodiments, the bioreactor may include in the liquid-medium containment vessel two liquid-medium circulation chambers as described above, wherein the first electrode is positioned within a first liquid-medium circulation chamber that is in fluid communication with a first separate liquid-medium reservoir comprising a first ion trap, and the second electrode is positioned within a second liquid-medium circulation chamber that is in fluid communication with a second separate liquid-medium reservoir comprising a second ion trap. For example, according to one such embodiment the first electrode is an anode and the second electrode is a cathode, and the selectivities of the first and second ion traps may be for distinct ionic species. As another example, in certain such embodiments the liquid medium delivered by at least one circulating means to at least one circulating chamber may be fresh medium from the separate reservoir, or may be medium enriched in a specific medium component or deficient in a specific medium component. Numerous variations in the materials, devices and methods of this invention, within the scope of the appended claims, will occur to those skilled in the art in light of the present disclosure.

### BIOLOGICAL SOURCE

A biological source cell may comprise any cell or tissue preparation derived from a biological source in which viable and preferably intact cells are present. In most preferred embodiments biological source cells are present in suspension in liquid medium, either as single cells or as aggregates which may be homogeneous or may be heterogeneous with respect to cell type. Biological source cells may be provided, for example, by obtaining a characterized or uncharacterized specimen from a laboratory, a clinic or from the field, or by obtaining a tissue explant, organ culture, blood sample, biopsy specimen or any other tissue or cell preparation from a biological source. As noted above, in certain embodiments biological source cells may be present in the form of plants or plant tissues, such as in a hydroponic bioreactor configuration, or in the form of other biological material, for example, in aquaculture.

The biological source may be a prokaryote, for example a bacterium such as Escherica coli, Staphylococcus aureus, Pseudomonas aeruginosa or Bacillus thuringiensis. The biological source may also be an archaebacterium, for example, Marinococcus or Sutfolobus shibatae. The biological source may also be a eukaryote, such as a yeast, a fungus, a plant, an invertebrate animal or a vertebrate animal, including a human or non-human vertebrate. Examples of biological sources that are yeasts include Phaffia rhodozyma (source of the widely used pigment astaxanthin), Saccharomyces cerevisiae, Schizosaccharomyces pombe, Pichia pastoris, Pichia stipitis, Candida utilis, Candida albicans, Candida guilliermondii and Cryptococcus albidus.

Biological sources that are fungi for use according to the present invention include, for example, Metarhizium flavivoride, Beauvueria bassiana, Paecilomyces fumosoreus, Gladiocladium fimbriatum and other fungi for which enhanced biomass production may be desirable. Such fungi include, for example, edible mushroom species and fungal species that specifically infect one or more insect species, and thus may provide useful vectors for specific biocides such as insecticides. Biological sources that are plants for use according to the present invention include any of numerous plant species that provide cells amenable to culturing as provided herein, for example, Taxus brevifolia (i.e., Pacific yew, the source of Taxol).

Other biological sources for use according to the present invention include invertebrate animals, for example, nematodes (eg., C. elegans), insects (e.g., Spodoptera frugiperda, Estigmene acrea or Trichoplusia ni) and other invertebrates. A biological source that is a vertebrate animal for use according to the present invention may be a reptile, an amphibian, a bird, a fish or a mammal. In certain preferred embodiments, the biological source may be a mammal, such as a human, a non-human primate, a rodent, a bovine, an equine, an ovine or a porcine animal. Thus, according to the present invention, a biological source from which a biological source cell may be derived includes a human or non-human animal, a primary cell culture or culture adapted cell line including but not limited to genetically engineered cell lines that may contain chromosomally integrated or episomal recombinant nucleic acid sequences, immortalized or immortalizable cell lines, somatic cell hybrid or cytoplasmic hybrid cell lines, differentiated or differentiatable cell lines, transformed cell lines and the like. Numerous biological source cells are known to those having ordinary skill in the art and are available from a variety of sources, including, for example, the American Type Culture Collection (ATCC, Manassas, Va.).

### WAVEFORM REGULATED ELECTRIC FIELD POTENTIAL

According to the present invention, there are provided an apparatus and processes for enhancing biomass production by ion injection into a liquid medium containing a biological source cell in a bioreactor, and by ion migration through the liquid medium. The present invention is directed in part to waveform regulated electric field potentials (i.e. alternating or direct current) whereby a repeating waveform governs the magnitude of an applied field over time, the waveform having two or more modes that order the application of field potentials to optimize volumetric productivity. A first waveform mode generates an ion from an ionizable component of the liquid medium, and a second waveform mode induces migration of the ion in the liquid medium. Optionally, a plurality of similar or dissimilar waveform modes may be included within a waveform according to the methods of the present invention. The present disclosure also provides the unexpected finding that an optional lag phase (eg., a period of reduced or no applied electric field potential) between such first and second waveform modes (and potentially between others of the plurality of modes that may comprise the waveform) may further optimize volumetric productivity, where such a lag phase may be a function of one or more variable factors to which the present invention pertains, including the selection of biological source cell and liquid medium, the size and geometric configuration of the liquid-medium containment vessel of the bioreactor, the applied electric field potentials and possibly other factors.

Ion injection may be achieved by initiating the generation of at least one ionic species at electrode surfaces through application of an electric field potential, wherein the field potential is a voltage pulse regulated by electrical waveform shaping. For example, to provide ion injection in particularly preferred embodiments of the invention, positive and/or negative waveform induced electrodes may be sites for generation of monatomic oxygen (O⁻) anions in an aqueous liquid medium by electrolytic dissociation of water. Depending on the biological source cell, the liquid medium and the waveform, other gaseous ions may be generated to enhance biomass production, for example CO₂, ammonium, nitrate or other ions.

Accordingly, ion injection provided by applying a waveform regulated electric field potential obviates the need for bubbling gas through liquid media in bioreactors (sparging), or for employing airlift devices in bioreactors, and thus avoids the mechanical damage (e.g., shearing) to cells associated with sparging or airlift mixing in bioreactors. Ion migration (also referred to as ion irrigation) within liquid medium in a bioreactor may also be achieved through application of a distinct waveform mode field potential, whereby ions generated by ion injection are induced to migrate within the applied field. Thus, the voltage used to induce migration of the ions produced by the initial pulse (e.g., first waveform mode), and the duration of the subsequent applied migration voltage (e.g., second waveform mode) provide electrically induced diffusion of one or more desired ionic species throughout the liquid medium, where availability of such ions to the biological source cells promotes biomass production.

Variations in the particular waveform selected will be determined in part by the particular bioreactor, biological source cell and liquid medium that are employed. As a further variation, the waveform may in certain embodiments be applied alternatingly with forward and reversed polarity to the bioreactor electrodes, to enhance the electrohydrodynamic mixing of ions generated and migrated in the liquid medium by the waveform regulated electric field potential. For example, such electrohydrodynamic mixing may be enhanced by including in the liquid medium a stable, charged suspension particle having a buoyant density at or near that of the liquid medium, such that alternating reversals of electrode polarity may effect particle movement within the medium. In still other embodiments, the waveform itself may be varied during the course of a bioreactor production run, to alter distribution of ions within the medium. Thus, in addition to providing a waveform for enhancing biomass production by promoting cell growth, the present invention also contemplates, for example, a variant waveform that promotes separations of ionic species within liquid medium in the bioreactor. Various modifications of bioreactor configuration, components and contents may be considered within these contemplated embodiments, which may include, for example by way of illustration and not limitation, waveform-induced electrophoretic (or, e.g., isotachophoretic) migration of reactants and/or products within a liquid-medium bioreactor, or other separation techniques that may relate to molecular separations based on electrostatic properties.

Selection of a suitable waveform may be according to any of a variety of methods known in the art and based on the teachings provided herein. In preferred embodiments the waveform is regulated by a computer that can be programmed to control the electric field potential output of a suitable power source such as an AC or a DC power supply. As is well known in the art, such power supplies can be programmed to deliver an electric field potential, for example, as constant voltage (V), constant current (I) or constant power (W=I²R). In preferred embodiments according to the present invention, field potentials are delivered at constant current with voltage drops varying according to the particular waveform, but the invention need not be so limited. For example, one or more additional parameters (e.g., pH; electrochemical changes such as conductivity, resistance or capacitance; oxygen generation, etc.) may be monitored through the use of appropriate sensors optionally in contact with liquid medium at one or more locations within the bioreactor, such that feedback protocols that may modify the waveform can be activated. As noted above, the amount of voltage applied during each mode of the waveform, and the duration of each mode, influence the ionization of medium components and the diffusion or migration of ions so generated. In certain embodiments, the invention provides a method for purifying, isolating, removing, segregating, enriching or otherwise accumulating particular biomass products (e.g., liquid medium solutes such as proteins, peptides, lipids, nucleic acids, carbohydrates, metabolites, catabolites and the like; or liquid medium particles including cells, organelles, inclusion bodies, aggregates and the like; or other products) by selection of a waveform that orders a regulated field potential such that the desired products migrate to a specific zone or region within the bioreactor, from which they can be collected.

Waveforms that are suitable for a particular set of biological source cell growth conditions may be identified through the use of waveform generating software combined with optimization of parameters as provided herein. Potential drops required for electrolytic dissociation of ionizable species in solution are known for many ionizable components that are typically components of liquid media as described above and in the Examples, and methods for empirical determination of such potentials are well known in the art (see, e.g., CRC Handbook of Chemistry and Physics, CRC Press, Boca Raton, Fla.). For example, electrolytic dissociation of oxygen anion from water requires a potential of 12.3 V, while electrolytic dissociation of other ions from noncovalent complexes that may typically be components of liquid media (e.g., Na⁺, K⁺, Cl⁻) may require an applied field on the order of less than 0.5-1 V. Waveform-generating software may be employed and one or more parameters of volumetric productivity or other bioreactor solution conditions (e.g. cell density, pH, oxygen or CO₂ content, temperature, optical density, turbidity, viscosity, conductivity, dielectric constant, etc.) may be monitored, in order to optimize selection of a suitable waveform for enhanced biomass production using a particular biological source cell, liquid medium and bioreactor. Alternatively, an electric field-optimizing computer program, for example INFOLYTICA software (Infolytica Ltd., Montreal, Canada, www.infolytic.com) can be employed, whereby real-time multiple parameter monitoring of conditions at one or more discrete locations within the bioreactor can be conducted to identify the relative effects of different waveforms. These and related approaches to selecting a suitable waveform will be apparent to those familiar with the art, based on the teachings herein.

All publications and patent applications cited in this specification are herein incorporated by reference as if each individual publication or patent application were specifically and individually indicated to be incorporated by reference. Although the foregoing invention has been described in some detail by way of illustration and example for purposes of clarity of understanding, it will be readily apparent to those of ordinary skill in the art in light of the teachings of this invention that certain changes and modifications may be made thereto without departing from the spirit or scope of the appended claims.

The following Example illustrates the invention and is not intended to limit the same. Those skilled in the art will recognize, or be able to ascertain through routine experimentation, numerous equivalents to the specific substances and procedures described herein. Such equivalents are considered to be within the scope of the present invention.

### EXAMPLES

### Example 1

### Enhanced Growth of Saccharomyces cerevisiae in a Liquid-Medium Bioreactor with Electrical Waveform Shaping

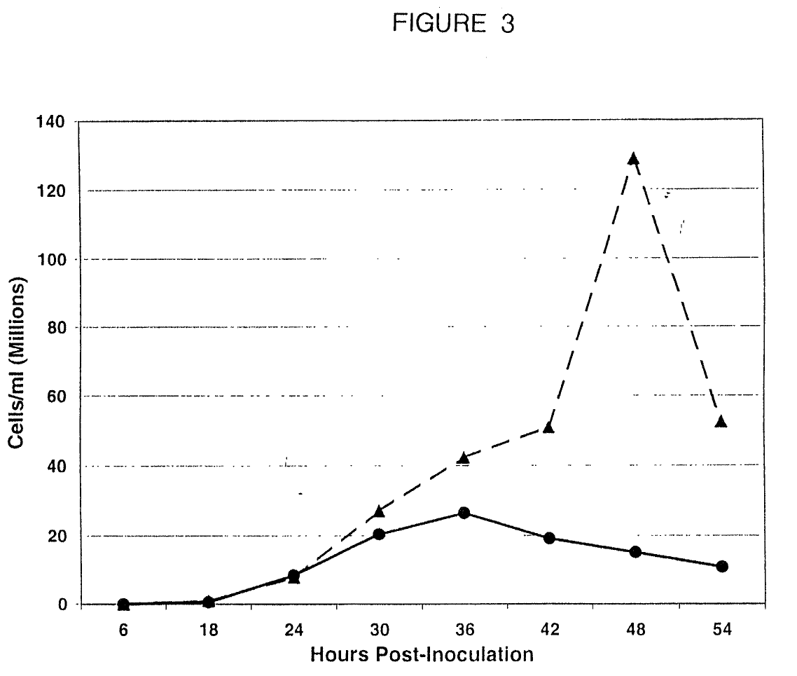

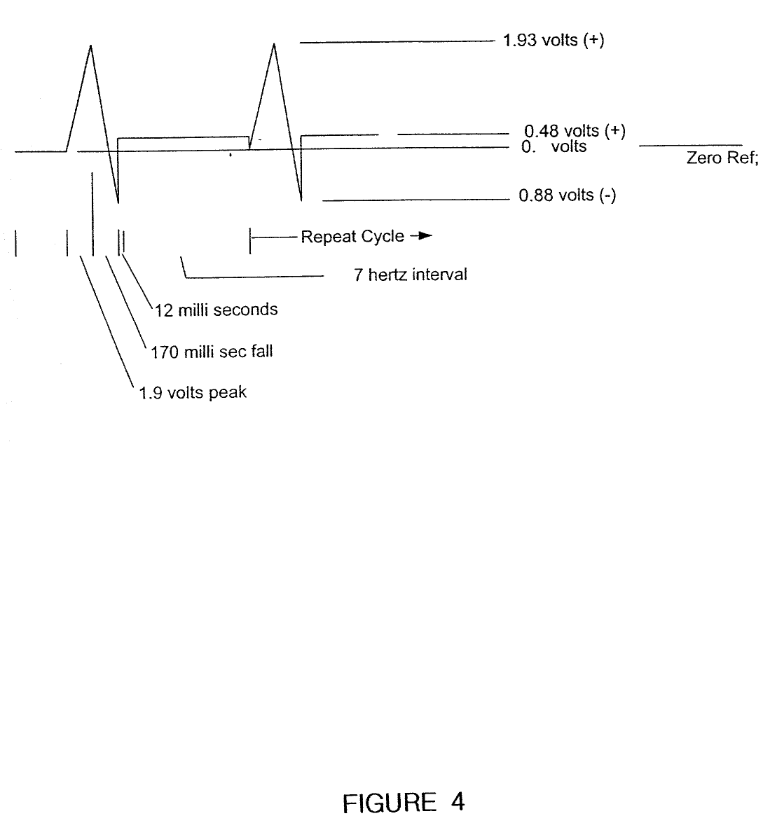

Saccharomyces cerevisiae (strain 1098) inoculum was obtained from commercial sources and cultures were initiated using standard methods. Control and experimental cylindrical glass liquid-medium bioreactor-fermentors (length 14 inches, diameter 6 inches, fitted at either end with stainless steel mesh electrodes) were inoculated with log phase cultures to a final concentration of 10⁴ per milliliter. The medium used was standardized per published protocols for S. cerevisiae (1% w/v yeast extract, 2% w/v tryptone peptone, 2% w/v dextrose). Following inoculation, the bioreactors were interconnected and the vessels were cross-circulated for six hours prior to the initiation of quantitative analysis to ensure homogeneous starting parameters. At six hours post-inoculation, cell counts were taken for confirmation and the run was started, with the experimental bioreactor (but not the control) continuously receiving the waveform-regulated applied electric field potential depicted in FIG. 4. Cell counts, pH, and temperature readings were taken at six hour intervals beginning 18 or 24 hours post-inoculation. Results are shown in FIG. 3, wherein cell counts from the control bioreactor (circles) and cell counts from the experimental bioreactor exposed to the waveform-regulated applied electric field potential (triangles) were plotted as a function of time.

From the foregoing it will be appreciated that, although specific embodiments of the invention have been described herein for purposes of illustration, various modifications may be made without deviating from the spirit and scope of the invention. Accordingly, the invention is not limited except as by the appended claims.

What is claimed is:

1. A method for enhancing biomass production in a bioreactor, comprising:
providing a liquid-medium bioreactor that comprises
(a) a liquid-medium containment vessel having an axis and comprising a wall and a floor and containing a liquid medium, and
(b) a first and a second electrode mounted on said wall and mutually opposed along said axis of the liquid-medium containment vessel and immersed in the liquid medium, wherein
(i) the first electrode comprises a first electrode surface and the second electrode comprises a second electrode surface, and said first and second electrode surfaces are substantially parallel to one another, and
(ii) the first and second electrodes are insulated from said wall and said floor of the containment vessel,
wherein said liquid medium comprises at least one ionizable component; and
applying a waveform-regulated electric field potential to at least one biological source cell within the liquid medium in the liquid-medium bioreactor,
wherein said waveform regulated electric field potential comprises a first waveform mode field potential capable of generating at least one ion from the ionizable component when applied to the liquid medium, and a second waveform mode field potential capable of inducing migration of said ion within the liquid medium when said second waveform mode field potential is applied to the liquid medium,
and thereby enhancing biomass production in the bioreactor.

2. The method of claim 1 wherein:
(a) the liquid-medium containment vessel further comprises at least one liquid-medium circulation chamber immersed in the liquid medium, said circulation chamber being in fluid communication with a separate liquid-medium reservoir;
(b) at least one electrode of the liquid-medium containment vessel is positioned within the liquid-medium circulation chamber, said liquid-medium circulation chamber comprising
(i) a continuous permeable membrane wall situated between the electrode and the biological source cell, and
(ii) a conduit to said separate liquid-medium reservoir; and
(c) said separate liquid-medium reservoir comprises
(i) a closed tank having liquid medium therein,
(ii) a circulating means for circulating liquid medium between the liquid-medium circulation chamber and the separate liquid-medium reservoir, and
(iii) an ion trap in fluid communication with the interior of the tank; whereby
circulation of liquid medium between the liquid-medium circulation chamber and the separate liquid-medium reservoir permits trapping of at least one ion from the liquid medium in the ion trap.

3. The method of claim 2 wherein
(a) the first electrode is positioned within a first liquid-medium circulation chamber that is in fluid communication with a first separate liquid-medium reservoir comprising a first ion trap, and
(b) the second electrode is positioned within a second liquid-medium circulation chamber that is in fluid communication with a second separate liquid-medium reservoir comprising a second ion trap, whereby
circulation of liquid medium between the first liquid-medium circulation chamber and the first separate liquid-medium reservoir permits trapping of at least one first species of ion from the liquid medium in the first ion trap and
circulation of liquid medium between the second liquid-medium circulation chamber and the second separate liquid-medium reservoir permits trapping of at least one second species of ion from the liquid medium in the second ion trap.

4. The method of claim 1 wherein the waveform regulated electric field potential is bimodal.

5. The method of claim 1 wherein the waveform regulated electric field potential comprises at least three modes.

6. The method of claim 1 wherein the biological source is selected from the group consisting of a prokaryote, an archaebacterium and a eukaryote.

7. The method of claim 6 wherein the prokaryote is selected from the group consisting of Escherica coli, Staphylococcus aureus, Pseudomonas aerugitiosa, and Bacillus thuringiensis.

8. The method of claim 6 wherein the eukaryote is selected from the group consisting of a yeast, a fungus, a plant, an invertebrate animal and a vertebrate animal.

9. The method of claim 8 wherein the yeast is selected from the group consisting of Phaffia rhodozyma, Saccharomyces cerevisiae, Schizosaccharomyces pombe, Pichia pastoris, Pichia stipitis, Candida utilis, Candida albicans, Candida guilliermondii and Cryptococcus albidus.

10. The method of claim 8 wherein the fungus is selected from the group consisting of Metarhizium oride, Beauvueria bassiana, Paecilomyces fumosoreus and Gladiocladium fimbriatum.

11. The method of claim 8 wherein the plant is Taxus brevifolia.

12. The method of claim 8 wherein the invertebrate animal is selected from the group consisting of a nematode and an insect.

13. The method of claim 8 wherein the vertebrate animal is selected from the group consisting of a reptile, an amphibian, a bird, a fish and a mammal.

14. The method of claim 13 wherein the mammal is selected from the group consisting of a human, a non-human primate, a rodent, a bovine, an equine, an ovine and a porcine.

15. The method of claim 6 wherein the archaebacterium is selected from the group consisting of Marinococcus and Sulfolobus shibatae.

16. The method of claim 1 wherein the liquid medium is an aqueous medium.

17. The method of claim 1 wherein the liquid medium comprises 1% yeast extract, 2% tryptone peptone and 2% dextrose.

18. The method of claim 1 wherein the ionizable component is water.

19. The method of claim 1 wherein the ionizable component is an organic molecule having a hydroxyl group.

20. The method of claim 1 wherein the ion is selected from the group consisting of singlet oxygen, Cl⁻, Na⁺, K⁺ and ammonium.

21. The method of claim 1 wherein the first waveform mode field potential is at least 12.3 volts.

22. The method of claim 1 wherein the second mode field potential is not greater than one volt.

23. A method for enhancing biomass production in a bioreactor, comprising:
A. providing a liquid-medium bioreactor that comprises
(1) a liquid-medium containment vessel having an axis and comprising a wall and a floor and containing a liquid medium, and
(2) a first and a second electrode mounted on said wall and mutually opposed along said axis of the liquid-medium containment vessel and immersed in the liquid medium, wherein
(a) the first electrode comprises a first electrode surface and the second electrode comprises a second electrode surface, and said first and second electrode surfaces are substantially parallel to one another, and
(b) the first and second electrodes are insulated from said wall and said floor of the containment vessel,
(c) said liquid medium comprises at least one ionizable component,
(d) the liquid-medium containment vessel comprises at least one liquid-medium circulation chamber immersed in the liquid medium, said circulation chamber being in fluid communication with a separate liquid-medium reservoir,
(e) at least one electrode of the liquid-medium containment vessel is positioned within the liquid-medium circulation chamber, said liquid-medium circulation chamber comprising
(i) a continuous permeable membrane wall situated between the electrode and the biological source cell, and
(ii) a conduit to said separate liquid-medium reservoir, and
(f) said separate liquid-medium reservoir comprises
(i) a closed tank having liquid medium therein,
(ii) a circulating means for circulating liquid medium between the liquid-medium circulation chamber and the separate liquid-medium reservoir, and
(iii) an ion trap in fluid communication with the interior of the tank, whereby circulation of liquid medium between the liquid-medium circulation chamber and the separate liquid-medium reservoir permits trapping of at least one ion from the liquid medium in the ion trap; and
B. applying a waveform-regulated electric field potential to at least one biological source cell within the liquid medium in the liquid-medium bioreactor,
wherein said waveform regulated electric field potential comprises a first waveform mode field potential capable of generating at least one ion from the ionizable component when applied to the liquid medium, and a second waveform mode field potential capable of inducing migration of said ion within the liquid medium when said second waveform mode field potential is applied to the liquid medium,
and thereby enhancing biomass production in the bioreactor.
